(19) United States
(12) Patent Application Publication
(10) Pub. No.: US 2015/0092336 A1
(43) Pub. Date: Apr. 2, 2015

(54) Apparatus and method for improving thermal energy transfer

(71) Applicant: Nokia Corporation, Espoo (FI)

(72) Inventors: Mezhgan SAMADY, San Diego, CA (US); Mikko Juhani TIMPERI, Raisio (FI); Romeo DUMPIT, San Diego, CA (US); Vincent PHAN, San Diego, CA (US); Cachaulo VAN LAANEN, San Diego, CA (US)

(73) Assignee: Nokia Corporation, Espoo (FI)

(21) Appl. No.: 14/044,308

(22) Filed: Oct. 2, 2013

(51) Int. Cl. G06F 1/20; H05K 7/20

(52) U.S. Cl. CPC G06F 1/206; H05K 7/2039
USPC 361/679.31; 361/714; 29/428

(57) ABSTRACT

An apparatus or method for providing thermal energy transfer comprising; a circuit board, a housing connected to the circuit board, at least one electronic component contained within said housing, said housing comprising a aperture, wherein said housing is configured to receive a thermally conductive material through the aperture and said thermally conductive material couples thermal energy from said at least one electronic component.

### TECHNOLOGICAL FIELD

Embodiments of the present invention relate to an apparatus and method for providing improved thermal energy transfer. In particular, they relate to a housing and a thermally conductive material that is inserted into the housing and can improve the thermal energy transfer between a component within the housing and the housing or a surface external to the housing.

### BACKGROUND

Apparatus such as a conductive housing may prevent leakage of electromagnetic signals from electronic components. Conductive housings which prevent leakage of electromagnetic signals are commonly known as shielding cans. Electronic devices such as televisions or portable devices may need to shield one or a plurality of sensitive components in one or more shielding cans but with processing speeds of integrated circuits increasing, the heat being radiated from integrated circuits is also increasing. The integrated circuits must be kept as cool as possible in order to operate efficiently and at as high a processing speed as possible which means transferring heat away from the integrated circuit as efficiently as possible would be desirable despite being surrounded by a housing or a conductive housing.

### BRIEF SUMMARY

According to various, but not necessarily all, examples of the disclosure there may be provided an apparatus comprising; a circuit board, a housing connected to the circuit board, at least one electronic component contained within said housing, said housing comprising a aperture, wherein said housing is configured to receive a thermally conductive material through the aperture and said thermally conductive material couples thermal energy from said at least one electronic component.

In some examples the thermally conductive material extends through the aperture and is configured to be adhered to a surface external to the housing.

In some examples the surface is at least one of: a conductive housing, a battery or a shield for a display.

In some examples the thermally conductive material comprises a gasket that is configured to be compressed in said housing.

In some examples the thermally conductive material comprises a flexible film.

In some examples the conductive housing comprises a second aperture through which the flexible film is configured to be pulled.

In some examples the second aperture comprises an edge configured to cut the flexible film.

In some examples the thermally conductive material comprises a gasket and a graphite layer.

According to various, but not necessarily all, examples of the disclosure there may be provided a method for providing thermal energy transfer in an apparatus comprising; partially enclosing at least one electronic component in a conductive housing; and inserting a thermally conductive material into a aperture of said housing; and coupling the thermally conductive material to the electronic component.

In some examples the method further comprises inserting a flexible film that is attached to the thermally conductive material through a first and second aperture to create a pulling force to insert the thermally conductive material through said first slot.

In some examples the flexible film is attached to a first and second surface of the thermally conductive material.

In some examples the thermally conductive material is adhered to a surface external to the conductive housing.

According to various, but not necessarily all, examples of the disclosure there is provided an apparatus comprising; a circuit board, a housing connected to the circuit board, at least one electronic component contained within said conductive housing, a thermally conductive material extending from within the and through an aperture in said housing.

According to various, but not necessarily all, examples of the disclosure there may be provided a thermal conductive material comprising a substantially planar first and second surface comprising a graphite layer a compressible gasket and a flexible layer, said flexible layer configured to be inserted into a conductive housing and adhered to a surface external to the conductive housing.

In some examples the flexible layer is attached to the first and second surface.

In some examples the thermally conductive material comprises a copper layer and the flexible film covers at least a portion of the copper layer

In some examples the thermally conductive material comprises a removable film.

In some examples the thermally conductive material may be adhered to a surface external to the conductive housing once the removable film is removed.

In some examples the flexible film may be perforated to assist in at least its partial removal from the thermally conductive material.

### BRIEF DESCRIPTION

For a better understanding of various examples that are useful for understanding the detailed description, reference will now be made by way of example only to the accompanying drawings in which:

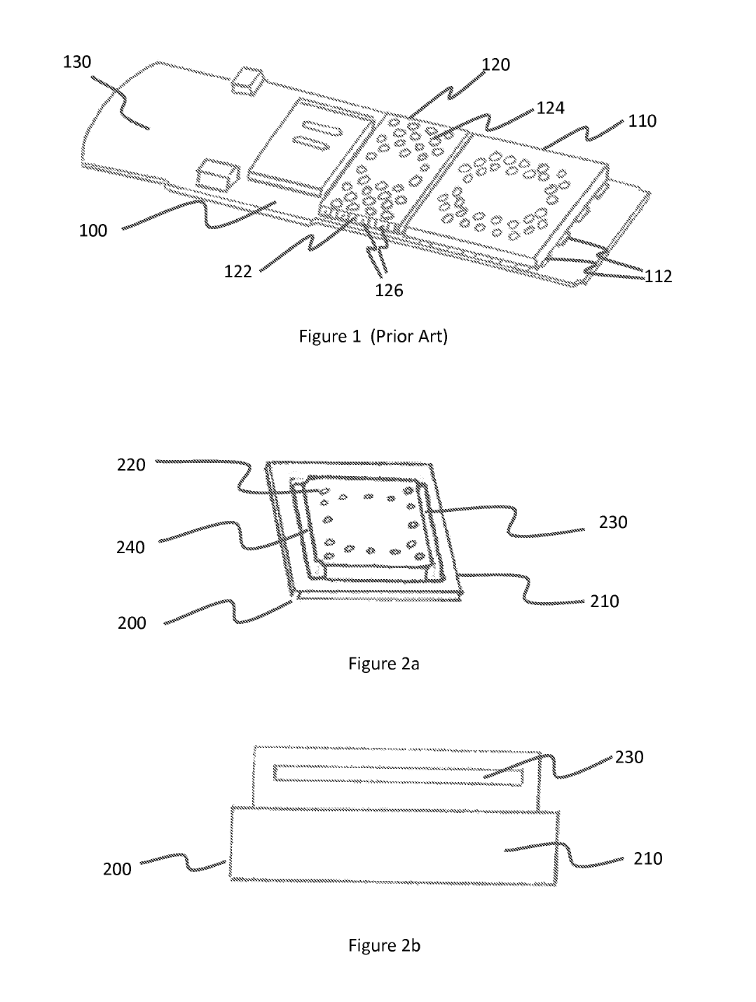

FIG. 1 illustrates a printed circuit board with a shielded housing;

FIGS. 2a-2b illustrate a housing according to an exemplary embodiment of the invention;

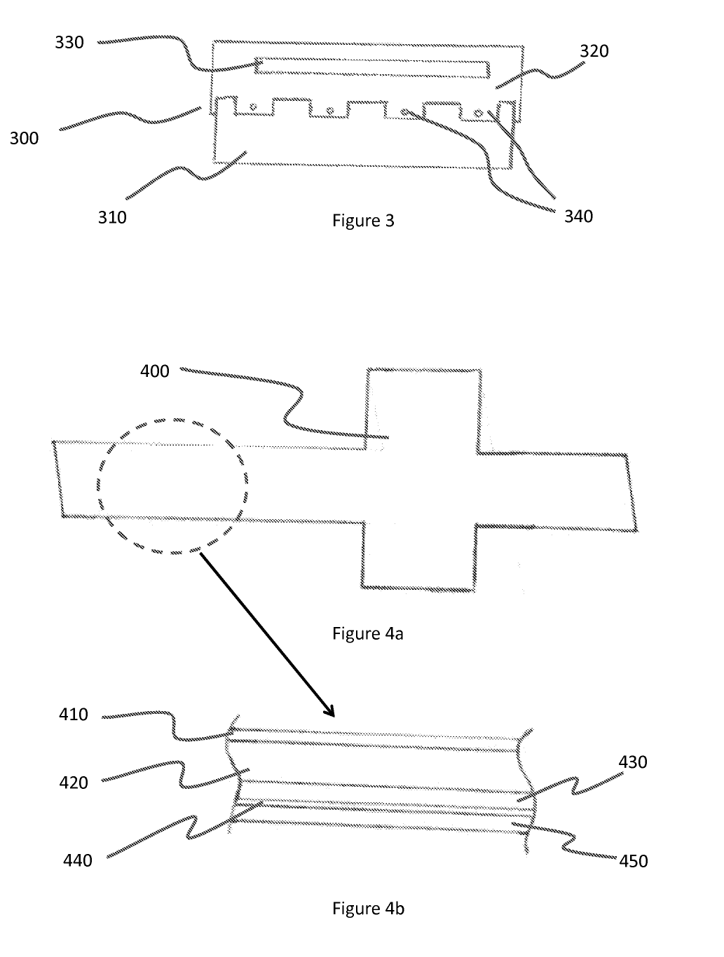

FIG. 3 illustrates a housing according to another exemplary embodiment of the invention;

FIGS. 4a-4b illustrate a thermally conductive material;

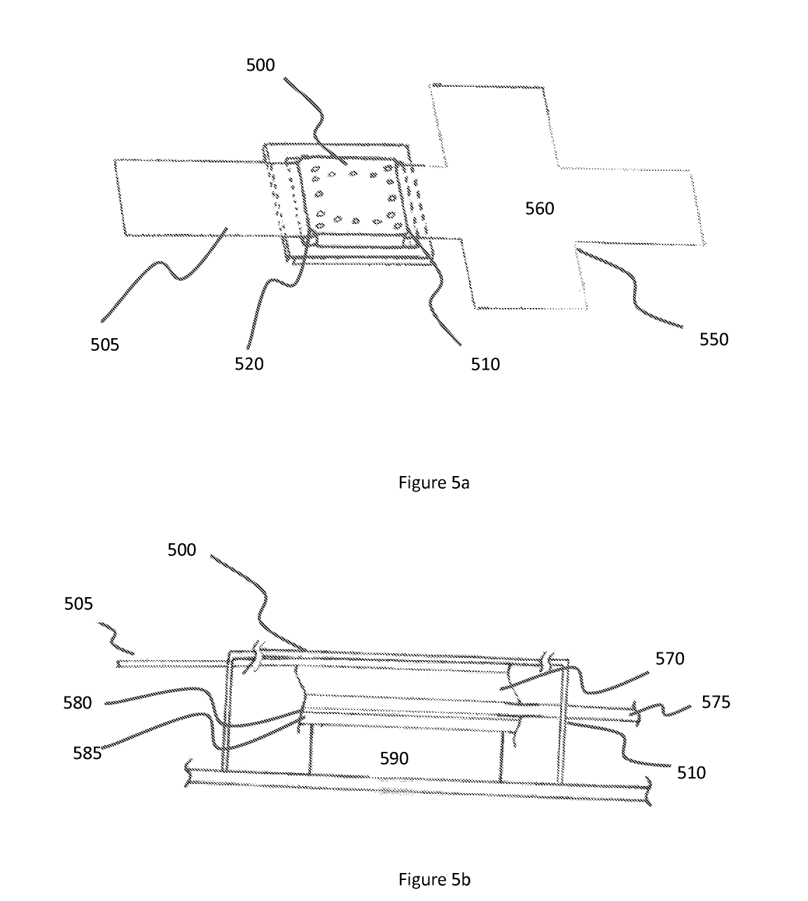

FIGS. 5a-5b illustrate a thermally conductive material partially contained within a housing;

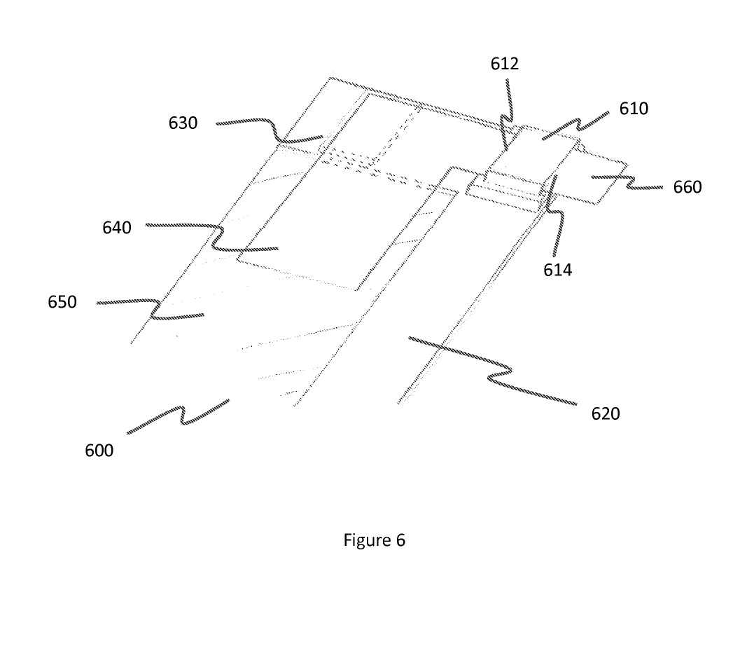

FIG. 6 illustrates a printed circuit board with a plurality of housings and the thermally conductive layer; and

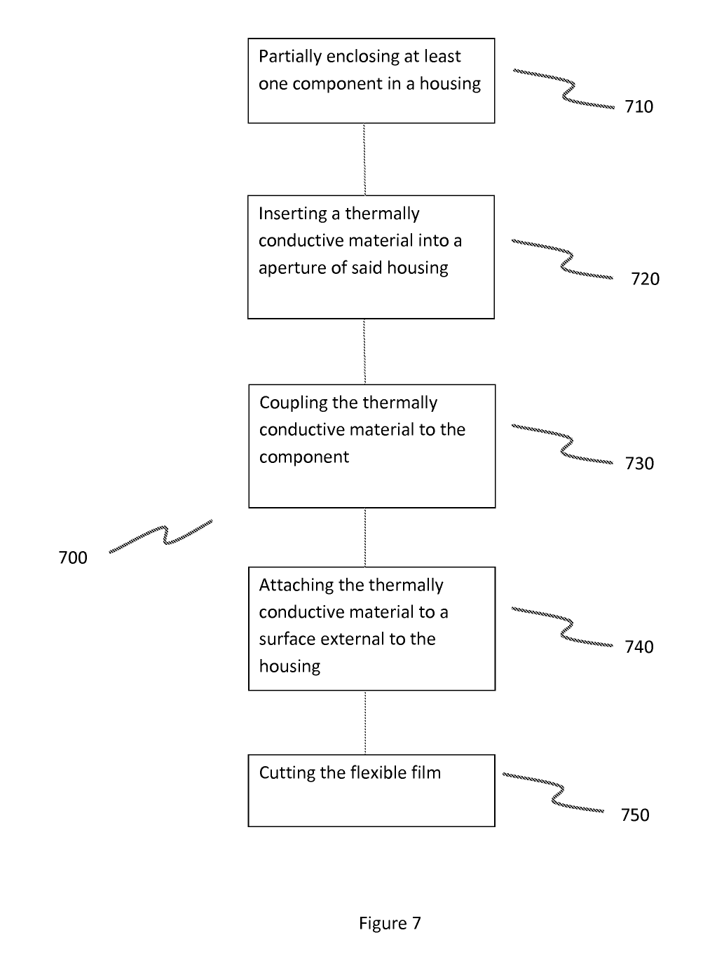

FIG. 7 illustrate a flow diagram for providing improved thermal energy transfer;

### DETAILED DESCRIPTION

FIG. 1 schematically illustrates a prior art example of a printed circuit board 100 comprising a first housing 110 and a second housing 120 connected to a first major surface 130 of the printed circuit board 100. The first housing 110 and second housing 120 are conductive shielding cans that inhibit the transmission of electromagnetic energy from components (not shown) within the housings 110, 120.

They also inhibit the transmission of interfering signals to components within the housings 110, 120.

The first housing 110 illustrates a unitary shielding can; that is the housing is connected directly to the printed circuit board, using solder tabs 112 along the perimeter of the housing. With such an arrangement re working of components within the housing is not usually possible. The second housing 120 illustrates a two part shielding can having a lower portion 122 and a lid 124. The lower portion is connected directly to the printed circuit board in a similar way to the first housing 110. The lid 124 is typically a push fit arrangement so it is coupled to the lower portion 122 by a plurality of coupling tabs 126 that create a pressure fit against surfaces of the lower portion 122. With this arrangement the lid is more easily removed compared to the first housing and so the reworking of components within the second housing 120 is easier compared to that of the first housing 110.

With both the first and second housings heat generated by the components within the housings is not easily dissipated resulting in the internal temperature within the housings increasing when the components are operational. Components such as processors and memories are operating at ever increasing speeds and to maintain high speeds and efficient operation the components must be kept as cool as possible.

In the example of FIG. 2a, a housing 200 is shown, the housing is a unitary housing comprising a lower portion 210 an upper portion 220, a first aperture 230 and a second aperture 240. The housing may be electrically non-conductive or in other examples the housing may be a conductive housing so that it acts as an electromagnetic shield. As outlined in FIG. 1 the housing is dimensioned to cover at least one electronic component. In other examples, the housing 200 may only have one aperture and it is appreciated that the shape of the housing 200 may vary significantly from that shown.

FIG. 2b shows a side view of the housing 200, with the first aperture 230 and the lower portion 210. In this example, the first aperture is a slot but this aperture or aperture 330 as shown in FIG. 3, apertures 510, 520 of FIG. 5, apertures 612, 614 of FIG. 6, may have other shapes and need to be dimensioned so that they are able to receive a thermally conductive material as shown in FIG. 4. In the examples where the housing is also a conductive housing so as to act as a shielding can the dimensions of the aperture may be determined by the requirement to inhibit the transmission of electromagnetic waves to and/or from the components within the conductive housing. The aperture is therefore dimensioned so as to receive the thermally conductive material and inhibit the transmission of electromagnetic waves to and/or from the components within the conductive housing.

The lower portion 210 of the housing 200 is connected to a printed circuit board, the connection may be done with use of solder around the perimeter of the housing if it is electrically conductive or by a bonding material if the housing is not electrically conductive.

FIG. 3 illustrates another example of a housing 300. The housing 300 has a lower portion 310, an upper portion 320 and an aperture 330. The upper portion is coupled to the lower portion by a plurality of coupling tabs 340 around the perimeter of the upper portion 320. The aperture 330 is located in the upper housing. In an alternative embodiment the aperture 330 may be located in the lower portion 310.

As with the housing 200 of FIG. 2, the lower portion may be connected to a printed circuit board in the same way. The upper portion 320 may be a lid that can be pressure fitted to the lower portion by the plurality of coupling tabs 340. It should be understood that these are merely examples for illustration and should not be considered limitations to these features.

FIG. 4a shows an example of a thermally conductive material 400. The thermally conductive material, such as the thermally conductive material 400 of FIG. 4a, is a planar sheet comprising a plurality of layers as shown by FIG. 4b. The thermally conductive material comprises a gasket 420, a Polyethylene terephthalate (PET) layer 430, a graphite layer 440 and a copper layer 450. The layers may be laminated or bonded together with an adhesive or combinations of lamination and bonding. It will be appreciated that while copper and graphite are outlined as example materials it is the objective of the invention to provide a thermally conductive material and as such other materials or combinations of materials may be used such as silver, aluminium, a carbon allotrope, and/or the like.

In another example, there is also a flexible film 410, which is bonded to the top surface of the thermally conductive material. This film can be pulled through a housing, such as housing 200 of FIG. 2a, 2b or housing 300 of FIG. 3 respectively, and in doing so pull the thermally conductive material into the housing. The flexible film may be manufactured as part of the thermally conductive material or it may be bonded to the thermally conductive material by a user. In an example (not shown) the flexible film may be bent so that it is also bonded to a lower surface of the thermally conductive material, in the example above it is bonded to the copper layer 450. This will improve the coupling between the flexible film 410 and the thermally conductive material and will also protect the copper layer 450 from being scratched or torn as it is slid into the housing. Once the thermally conductive material is located in the housing the flexible film that has been pulled through the first and second aperture, see section 660 of FIG. 6, may be cut. The cutting could be achieved by a serrated edge at the second aperture that a user can pull the flexible film towards and detach from the thermally conductive material. In another example the film may be perforated so that it is easily detachable after insertion.

In some examples the gasket is compressible. The gasket may be made of PORON urethane® or any other suitable compressible material, for example but not limited to vinyl sponge, neoprene sponge, sponge rubber, latex foam and solid viscoelastic.

It should be appreciated that FIG. 4b is not drawn to scale and the thickness of each layer can vary.

FIG. 5a shows an example of the housing of FIG. 2a and the thermally conductive layer of FIGS. 4a and 4b. The housing 500 has a first aperture 510 and second aperture 520. At least a part of the thermally conductive material 550 is shown having been inserted through a first aperture 510. The flexible film 505 can be seen to extend away from the second aperture having been inserted through the first aperture 510 then through the internal space within the housing 500 and then through the second aperture 520. The thermally conductive material also extends away from the first aperture by a section 560 that can be used to transfer thermal energy away from the housing 500.

FIG. 5b shows a cross sectional side view of the housing 500 with the thermally conductive material inserted. For clarity only a portion of the thermally conductive material has been shown and any of the layers may extend from the housing and out through the first and/or second aperture. A flexible film 505 can be seen extending away from the housing having been inserted into and then out through the housing via the first and second apertures. The flexible film 505 is attached to a gasket 570. The gasket is coupled to a PET 575. The PET 575 can be seen extending out of the first aperture 510. The PET 575 is coupled to a graphite layer 580; the graphite layer is coupled to a copper layer 585.

The copper layer 585 sits on a component 590, for example a processer, memory or other integrated circuit. In other examples, the thermally conductive material may be located above a plurality of components within the housing 500. While an example of the construction of the thermally conductive material has been provided it is appreciated that some of the layers may not be needed. In one embodiment the flexible film may not be needed and the remaining layers of the thermally conductive material are rigid enough to be inserted into the first aperture 510. In this embodiment the housing 500 may have a first aperture 510 but not a second aperture 520.

The thermally conductive layer is located above the component so as to transfer heat from the component into the thermally conductive layer and then away from the housing. The thermal energy may be transferred to the upper portion of the housing 500 and heat present on the upper portion of the housing may be dissipated by convection. The thermal energy may be transferred from the housing by the thermally conductive material conducting heat through the first aperture 510 and away from the housing 500.

In an example, the gasket 570 may be compressed upon insertion into the housing 500 through the first aperture 510. Compression of the gasket 570 can result in an improved physical contact between the thermally conductive material and the component 590. It is appreciated that if there is no air gap between the thermally conductive material and the component 590 then thermal energy transfer from the component to the thermally conductive material will be improved in comparison to an arrangement where an air gap is present. The housing 500 is a unitary housing connected to a printed circuit board 595 so compression of the gasket 570 is achieved because the compressive force being applied by the thermally conductive material as it is compressed is not sufficient to overcome the joint made by the connection between the printed circuit board and the housing 500.

In another example, where the housing is a two part housing as illustrated in FIG. 3 the force being applied by the gasket on the upper portion of the housing because of the compression of the gasket should not exceed the coupling force made by the coupling tabs of the upper portion when coupled to the lower portion. In this example the compression of the gasket is achieved as the user places the upper portion on top of the lower portion so as to complete the housing and so as the upper portion is placed on the lower portion a force is transmitted by the placement of the upper portion through the thermally conductive material and to the gasket.

It is appreciated that insertion of the thermally conductive material is done after at least a part of the housing has been connected to the printed circuit board. If a gasket that is compressible was placed in a housing that was not soldered then the force of the gasket may result in the housing not being properly connected to the printed circuit board as any connection points on the housing may be above the surface of the printed circuit board. Typically, during manufacture of an apparatus such as a television or portable electronic device the printed circuit board of such an apparatus may be populated with components and then those components are bonded to the printed circuit board using a reflow oven. If the components are not placed correctly on the PCB then the bonding will not take place or at least not be as good as when the component was sitting correctly on the printed circuit board. Therefore, an advantage of this invention is that the gasket or thermally conductive material may be compressed to provide an improved coupling as explained earlier without affecting the populating and subsequent bonding to the printed circuit board.

FIG. 6 shows part of an internal arrangement 600 for an electronic device comprising a housing 610 as earlier illustrated in FIG. 2. In an example embodiment, an electronic device may be a hand-portable device, a mobile phone or a Personal Digital Assistant (PDA), a Personal Computer (PC), a laptop, a desktop, a wireless terminal, a communication terminal, a game console, a music player, an electronic book reader (e-book reader), a positioning device, a digital camera, a CD- or DVD-player, a media player, and/or the like. The housing 610 has a first aperture 612 and second aperture 614. The housing is connected to a printed circuit board 620. The internal arrangement also shows a second housing 630, obscured mostly by the thermally conductive material and shown in dashed lines for clarity; which may be a further housing in accordance with earlier described housings of FIGS. 2-4 and/or alternatively a housing as known in the prior art of FIG. 1. In addition part of a battery 650 is shown.

A thermally conductive material 640 is shown having been partially inserted into housing 610. A flexible film 660 attached to the thermally conductive material 640 is shown extending from the second aperture 614. The thermally conductive layer extends through an interior cavity of the housing and out through the first aperture 612. In an example where the housing is unitary it is appreciated that the flexible film has been inserted through the first and second apertures and as it is pulled through the housing it pulls at least part of the thermally conductive layer into an interior cavity of the housing. The portion of the thermally conductive material that extends away from the housing 610 can be seen above a second housing 630 and at least partially above the battery 650. The portions of the thermally conductive material that lie above the housing and battery may be attached to the surface of the housing 630 and battery 650 by an adhesive. By coupling the thermally conductive material 640 to at least one further component external to the housing 610 thermal energy originating from a component in the housing 610 may be transferred to other areas of the electronic device via the thermally conductive material 640 so that high temperatures that may exist in one part of the electronic device relative to other parts of the electronic device may be mitigated

FIG. 7 illustrates a process 700 according to an embodiment of the present invention. At 710 at least one component is partially enclosed by a housing; the housing may be conductive to provide electromagnetic shielding or non-conductive. The housing may be a unitary housing and bonded to a printed circuit board using known manufacturing techniques such as using a solder re flow oven. The housing may be a two part housing in which case a lower portion of the housing may be bonded to a printed circuit board.

At 720 a thermally conductive material is inserted into an aperture of the housing. If the housing is a two part housing as outlined above then the aperture may be in a lid or upper portion of the housing. In an alternative example the thermally conductive material may comprise a flexible film or a flexible film may be attached to the thermally conductive material and used to pull the thermally conductive material into the housing via the aperture. The flexible film may be attached to a single surface of the thermally conductive material or bent so that it is attached to an upper and lower surface of the thermally conductive material. The flexible film would also be inserted through a second aperture in order to pull the thermally conductive material into the housing.

At 730 the thermally conductive material is placed so as to enhance thermal energy transfer from the component into the thermally conductive material. Thermal energy transfer may be enhanced by compression of a gasket that is part of the thermally conductive material as it is inserted into the housing.

At 740 the thermally conductive material which extends away from the housing may be coupled to a surface external to the housing; for example another housing, display shield or a battery. This will allow thermal energy stored in the thermally conductive material to transfer thermal energy or heat from an area where the temperature is higher to one which is lower.

At 750 where a flexible film has been used to assist the insertion of the thermally conductive material, a portion of the flexible film that extends away from the housing is cut. This portion can be cut by using a serrated edge on the housing or by perforations in the flexible film.

In the description, the wording ‘connect’ and ‘couple’ and their derivatives mean operationally connected or coupled. It should be appreciated that any number or combination of intervening components can exist (including no intervening components). Additionally, it should be appreciated that the connection or coupling may be a physical galvanic connection.

The blocks illustrated in FIG. 7 may represent steps in a method. The illustration of a particular order to the blocks does not necessarily imply that there is a required or preferred order for the blocks and the order and arrangement of the blocks may be varied. Furthermore, it may be possible for some blocks to be omitted.

The term “comprise” is used in this document with an inclusive not an exclusive meaning. That is any reference to X comprising Y indicates that X may comprise only one Y or may comprise more than one Y. If it is intended to use “comprise” with an exclusive meaning then it will be made clear in the context by referring to “comprising only one . . . ” or by using “consisting”.

In this description, reference has been made to various examples. The description of features or functions in relation to an example indicates that those features or functions are present in that example. The use of the term “example” or “for example” or “may” in the text denotes, whether explicitly stated or not, that such features or functions are present in at least the described example, whether described as an example or not, and that they can be, but are not necessarily, present in some of or all other examples. Thus “example”, “for example” or “may” refers to a particular instance in a class of examples. A property of the instance can be a property of only that instance or a property of the class or a property of a sub-class of the class that includes some but not all of the instances in the class.

Although embodiments of the present invention have been described in the preceding paragraphs with reference to various examples, it should be appreciated that modifications to the examples given can be made without departing from the scope of the invention as claimed.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavouring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

I/we claim:

1. An apparatus comprising:
a circuit board,
a housing connected to the circuit board,
at least one electronic component contained within said housing,
said housing comprising a aperture,
wherein said housing is configured to receive a thermally conductive material through the aperture and said thermally conductive material couples thermal energy from said at least one electronic component.

2. An apparatus according to claim 1 wherein the thermally conductive material couples thermal energy from said at least one electronic component to a surface of the housing.

3. An apparatus according to claim 1 wherein the thermally conductive material extends through the aperture and is configured to be adhered to a surface external to the housing.

4. An apparatus according to claim 3 wherein the surface is at least one of:
a shielding housing,
a battery,
a shield for a display.

5. An electronic device comprising the apparatus according to claim 4 wherein
the electronic component is at least one of:
a processor, a memory.

6. An apparatus according to claim 1 wherein the thermally conductive material comprises a gasket that is configured to be compressed in said housing.

7. An apparatus according to claim 1 wherein said thermally conductive material is fixed to a flexible film.

8. An apparatus according to claim 7 wherein said flexible film is fixed to a first and second surface of the thermally conductive material.

9. An apparatus according to claim 7 wherein said housing comprises a second aperture and the first and second aperture are configured to receive the flexible film.

10. An apparatus according to claim 9 wherein the flexible film is configured to pull the thermally conductive material into the housing upon insertion of the flexible film through the second aperture.

11. An apparatus according to claim 9 wherein the second aperture comprises an edge configured to cut the flexible film.

12. An apparatus according to claim 1 wherein the housing is a unitary housing.

13. An apparatus according to claim 12 wherein the housing is a electrically conductive shielding can.

14. An apparatus according to claim 1 wherein the thermally conductive material comprises a gasket and a graphite layer.

15. An apparatus according to claim 14 wherein the thermally conductive material is configured to be compressed between the housing and the electronic component.

16. An apparatus according to claim 15 wherein the thermally conductive material comprises a flexible film that is configured to pull the thermally conductive material into the housing.

17. An apparatus according to claim 16 wherein the housing comprises a second aperture and the flexible film is configured to be inserted through the first and second aperture.

18. A method for providing thermal energy transfer in an apparatus comprising:
partially enclosing at least one electronic component in a housing; and
inserting a thermally conductive material into at least a first aperture of said housing; and
coupling the thermally conductive material to the electronic component.

19. A method according to claim 18 wherein the housing comprises a second aperture and the thermally conductive material comprises a flexible film, and inserting the flexible film through the first and second aperture to create a pulling force to insert the thermally conductive material through said first aperture.

20. A method as claimed in claim 18 wherein a flexible film is attached to a first and second surface of the thermally conductive material.

21. A method as claimed in claim 19 wherein the flexible film is cut when the thermally conductive material is within the housing.

22. A method as claimed in claim 19 wherein the thermally conductive material is adhered to a surface external to the conductive housing.

23. An apparatus comprising:
a circuit board,
a housing connected to the circuit board,
at least one electronic component contained within said housing,
a thermally conductive material extending from within the housing and through an aperture in said housing.

24. An apparatus according to claim 23 wherein the thermally conductive material is attached to a surface exterior to the housing

25. An apparatus according to claim 24 wherein the surface is at least one of:—
a shielding housing,
a battery housing,
a shield for a display.
